(19) United States
(12) Patent Application Publication
(10) Pub. No.: US 2023/0377880 A1
(43) Pub. Date: Nov. 23, 2023

(54) ELECTRONICS UNIT AND METHOD FOR THE PRODUCTION THEREOF

(71) Applicant: SPHERA TECHNOLOGY GMBH, Muenchen (DE)

(72) Inventor: Janine-Melanie POTRECK, Muenchen (DE)

(73) Assignee: SPHERA TECHNOLOGY GMBH, Muenchen (DE)

(21) Appl. No.: 18/246,394

(22) PCT Filed: Sep. 24, 2021
(86) PCT No.: PCT/EP2021/076343

§ 371 Date: Mar. 23, 2023

(30) Foreign Application Priority Data
Sep. 24, 2020 (DE) 10 2020 124 955.1

(51) Int. Cl. H01L 21/02; H01L 23/00; H01L 21/768; H01L 23/06

(52) U.S. Cl. CPC H01L 21/02491; H01L 24/03; H01L 21/76885; H01L 23/06; H01L 21/02068; H01L 2224/03442

(57) ABSTRACT

A manufacturing method can be used to produce an electronics unit. The electronics unit contains a first component with a plurality of first electrical contacts, containing an integrated circuit, and a second component with a plurality of second electrical contacts. The first electrical contacts and the second electrical contacts are each electrically connected to each other via an electrically conductive structure containing a plurality of electrically conductive particles.

### TECHNICAL FIELD

The invention relates to an electronics unit, in particular with an integrated circuit, and a joining technology for electrically connecting two components of an electronics unit.

### TECHNICAL BACKGROUND

In electronics manufacturing, the individual fragments (chips; die) of a wafer are usually attached to a carrier structure and electrically connected to it. This is also known as chip bonding or die bonding. The carrier structure can be, for example, the housing of a chip or, in the case of chip-on-board technology, a substrate such as a printed circuit board, a ceramic substrate or a thick-film circuit, which can also carry other components. However, a chip can also be arranged on top of another chip (chip-on-chip technology), in which case a stacked arrangement of several chips is produced. In this case, the carrier structure would be another chip.

Various methods for mounting chips on a carrier structure are known from the prior art: Bonding with conductive or non-conductive adhesives, hot air soldering, wave soldering, reflow soldering (melting of solder baits) or wire bonding, to name just a few. In principle, the chips can be mounted by means of connecting wires (bonding wires) or directly, without further connecting wires.

In flip-chip assembly, for example, the unhoused chip is attached directly to a substrate by means of bumps, without any additional leads. In this case, the chips are provided with a large number of small solder balls, which are arranged next to each other in a grid of columns and rows (BGA, Ball Grid Array). During assembly, the chips are placed on the substrate with the solder balls facing down. The solder balls are then wetted with a flux agent and the assembly is heated so that the solder melts and creates an electrical connection between the contact surfaces of the chip and the contacts of the substrate (housing; package). This is also known as reflow soldering.

BGA technology enables particularly small dimensions between chip and substrate and short conductor lengths. The size of the bumps is now less than 100 μm. However, even smaller dimensions are desirable for special applications, especially in mobile communications technology.

### General Description

The present disclosure enables to provide and/or manufacture an improved electronics unit, in particular a compact electronics unit, for example with a reduced distance between neighboring electrical contacts and/or a reduced distance between chip and carrier structure.

This is made possible in particular by the features indicated in the independent claims. Further embodiments of the present disclosure are apparent from the dependent claims.

According to the present disclosure, an electronics unit is proposed comprising and/or having a first component with a plurality of first electrical contacts, such as an integrated circuit, and a second component with a plurality of second electrical contacts. According to the present disclosure, the first and second electrical contacts are electrically connected to each other via an electrically conductive structure comprising a plurality of or multiple electrically conductive particles that form an agglomerate due to their physical or chemical properties and connect bind to the first and second electrical contacts.

The particles and/or electrical contacts can, for example, be provided with at least one functional group and/or be functionalized so that the particles preferably bond with the electrical contacts, for example by weak interaction and/or covalent binding. The use of conventional joining technologies, such as soldering, adhesive bonding or ultrasonic welding, is not necessary in this case.

Said particles can be, for example, microparticles or nanoparticles and can have a wide variety of shapes, such as rod-shaped, spherical, star-shaped, or other geometries, etc. According to a preferred embodiment of the present disclosure, the particles are rod-shaped nanoparticles. In this case, the conductive structure comprises a plurality of nanoparticles aligned in parallel in a predetermined direction, which can be in contact with each other.

For example, each of the conductive structures can include a plurality of conductive particles that may be aligned parallel to each other. At least a portion of the conductive particles can extend from one of the first electrical contacts of the first component toward an oppositely arranged second electrical contact of the second component. In particular, a longitudinal extension direction of at least a portion of the particles can be oriented substantially parallel to a surface normal vector of the first and/or second contacts.

Optionally, each of the conductive structures can comprise a plurality of particles which can be arranged adjacent to each other in a direction parallel to the first and/or second electrical contacts (or perpendicular to a surface normal vector of the first and/or second contacts). Particles arranged directly next to each other can be at least partially in contact with each other, so that an electrically conductive connection can be formed between the particles.

Alternatively or additionally, each of the conductive structures can comprise a plurality of particles which can be arranged in series parallel to a surface normal vector of the first and/or second contacts. Particles arranged directly in series can be at least partially in contact with each other, such that an electrically conductive connection can be formed between the particles. For example, each conductive structure can include a plurality of particles, which may be arranged side-by-side and one behind the other in a manner similar to a brick pattern.

The particles are electrically conductive and preferably consist (at least in part) of a semi-metallic and/or a metallic material and/or polymer, ceramic and/or such as gold, silver, copper and/or bronze, tin, zinc, lead, tungsten, mercury or alloys thereof and/or have a metallic surface coating. In addition, other materials would be conceivable, such as carbon nanotubes, graphene, graphite, semiconductors (silicon, germanium), fullerenes, polytetrafluoroethylene.

A surface coating of the particles can be achieved, for example, by functionalizing with (terminal) reactive groups, in particular with polymers which have at least one thiol group, such as 11-mercaptoundecanoic acid or similar, or several thiol groups, such as dithiols, in particular 1,2 ethanedithiol, 1,3-propanedithiol, 1,4-butanedithiol, 1,5-pentanedthiol, benzene-1,4-dithiol, 2,2′-ethylenedioxydiethanethiol, 1,6-hexanedithiol, tetra(ethylene gycol)dithiol, 1,8-octanedithiol, 1,9-nonanedithiol, 1,11-undecanedithiol, hexa(ethylene glycol)dithiol, 1,16-hexadecanedithiol, or the like. The functionalized particles selectively bind to metal particles, which attach along the surface of the functionalized particles and form the coating.

According to one embodiment of the present disclosure, at least one of the following elements is functionalized, i.e. provided with at least one functional group: the particles, the first contacts, the second contacts. Functionalization results in selective binding of the element in question to another substance and/or element. For example, functionalizing an element with a thiol group leads to enhanced bonding of the element in question to metallic surfaces.

In one embodiment, for example, only, exclusively and/or only the particles may be functionalized so that they bind and/or adhere better to the metal surfaces of the first and second contacts. In this regard, the first and/or the second contacts may each have no functionalization and/or be non-functionalized. In other words, the first and/or second contacts can be untreated and/or uncoated. At least a portion of the particles may, for example, be bonded to at least one of the first contacts and the second contacts via weak interaction. This may improve an electrical connection between the particles and the first and/or second contacts. Also, this can enable a targeted and controlled formation of the conductive structures, which can enable an overall more compact design of the electronics unit. In addition, a distance between directly neighboring first contacts of the first component and/or directly neighboring second contacts of the second component can be reduced, which can further reduce a size of the electronics unit.

In another embodiment, the particles and at least one of the first contacts and/or at least one of the second contacts are functionalized. For example, the particles and all of the first contacts can be functionalized, wherein the second contacts may not be functionalized. Alternatively, the particles and all of the second contacts can be functionalized, wherein the first contacts may not be functionalized. Alternatively, the particles, the first contacts, and the second contacts can be functionalized.

In another embodiment, the electrical contacts or both elements, namely the electrical contacts and the particles, can be functionalized.

Functionalizing metallic nanoparticles is known, for example, from WO 2015/103028 A1, CA 2712306 C, and U.S. Pat. No. 8,790,552 B2. Thiol functionalizations are known, for example, from Kelton J. E., Young S. L., & Hutchison J. E. (2019). “Engineering the Nanoparticle-Electrode Interface”, Chemistry of Materials, 31(8), 2685-2701, further from Kubackova J., et al. (2014), “Sensitive surface-enhanced Raman spectroscopy (SERS) detection of organochlorine pesticides by alkyl dithiol-functionalized metal nanoparticles-Induced plasmonic hot spots”, Analytical chemistry 87.1, 663-669, also from Ahonen P., Laaksonen T., Nykanen A., Ruokolainen J., & Kontturi K. (2006), “Formation of stable agnanoparticle aggregates Induced by dithiol cross-linking”, The Journal of Physical Chemistry B, 110(26), 12954-12958 and from Dong T. Y., Huang C., Chen C. P., & Lin M. C. (2007), “Molecular self-assembled monolayers of ruthenium (II)-terpyridine dithiol complex on gold electrode and nanoparticles”, Journal of Organometallic Chemistry, 892(23), 5147-5155.

Depending on the application, there are various suitable functional groups, such as: Alkanes, cycloalkanes, alkenes, alkynes, phenyl substituents, benzyl substituents, vinyl, allyl, carbenes, alkyl halides, phenol, ethers, epoxides, ethers, peroxides, ozonides, aldehydes, Hydrates, imines, oximes, hydrazones, semicarbazones, hemiacetals, hemiketals, lactols, acetal/ketal, aminals, carboxylic acid, carboxylic acid esters, lactones, orthoesters, anhydrides, imides, carboxylic acid halides, carboxyl groups, carboxylic acid derivatives, amides, lactams, peroxyacids, nitriles, carbamates, hydrogens, guanidines, carbodiimides, amines, aniline, hydroxylamines, hydrazines, hydrazones, azo compounds, nitro compounds, thiols, mercaptans, sulfides, phosphines, P-Ylene, P-Ylides, biotin, streptavidin, metallocenes, or the like, which bind to different degrees or bind to different partners. One or more of the aforementioned functional groups can be used to functionalize the particles, the first contacts and/or the second contacts.

According to a preferred embodiment of the present disclosure, one of the aforementioned elements, i.e. the particles, the first contacts and/or the second contacts (in particular the particles), is functionalized with a carboxyl group and another element of the particles, first contacts and second contacts (e.g. the first and/or second electrical contacts) is functionalized with primary amines. The carboxyl group is preferably activated with EDC/NHS, causing the two elements (particles and first and/or second electrical contacts) to form a covalent bond. Subsequently, the still free functional groups can optionally be blocked with ethanolamine.

According to another embodiment of the present disclosure, one of the aforementioned elements, i.e., the particles, the first contacts and/or the second contacts (in particular, the particles), is functionalized with a thiol group. At least one other element of the particles, first contacts, and second contacts (e.g., the first and/or second electrical contacts) are not functionalized. In this case, selective bonding between the elements may occur via weak interaction.

It can also be provided for binding the particles to the first contacts via weak Interaction and binding the particles to the second contacts via covalent bonds. Alternatively, it is possible to bind the particles to the second contacts via weak interaction and to bind the particles to the first contacts via covalent bonds.

The particles and electrical contacts can each be functionalized with one or more identical, or with different functional groups.

The particles are preferably capable of self-aligning in a specific direction. This property of self-alignment can be achieved, for example, by thiol groups and/or Janus-(nano)-particles and/or patchy particles and/or by magnetism (particles and surface are magnetic) and/or via an electrostatic Interaction. Such interactions can be achieved, for example, by a positively charged or negatively charged surface and/or via weak interactions and/or via chemical reaction(s) such as click chemistry (e.g. thiol-ene click chemistry), Michael reaction, or the like.

The first component mentioned at the beginning can be, for example, a housed (packaged) chip, a raw chip (die) or an electronic system with several chips and possibly other components (with or without a housing). The second can may be a housing, a chip, a printed circuit board or another substrate.

According to a particular embodiment of the present disclosure, the first component is a raw chip and the second component is a printed circuit board, chip housing, or other substrate.

According to one embodiment of the present disclosure, the first and/or second component comprises one or more spacers dimensioned such that opposing contact areas of the first and second contacts are spaced apart. The spacing can be, for example, a few μm, e.g., 20 μm, or can be in the nm range, e.g., 100 nm or less.

The contacts of the first and/or second component preferably have a flat contact surface, but they can also have a ball-shaped, concave or convex surface. A concave contact surface is particularly advantageous when capsules containing the conductive particles are applied to the electrical contacts. The contacts of a component preferably lie in the same plane.

The electrically conductive structure of electrically conductive particles mentioned at the beginning can be produced in different methods. According to a first option proposed here, a suspension containing the particles as suspended matter is applied directly to at least one of the components. According to a second option, a suspension with capsules containing the electrically conductive particles is applied to at least one of the components. Alternatively, the capsules can also be applied as a powder.

With respect to the first option, the present disclosure relates to a method of manufacturing an electronics unit with a first component comprising a plurality of first electrical contacts, such as in the form of an integrated circuit, and a second component with a plurality of second electrical contacts, wherein at least the following steps are performed:
Producing and/or providing a suspension containing particles as suspended matter,
Applying the suspension to at least one of the components such that an electrically conductive structure comprising and/or having one or more of the electrically conductive particles forms on the electrical contacts of the at least one component,
Arranging the first and second components at a predetermined distance, with opposing first and second contacts, wherein applying the suspension can take place, for example, before or after the arranging of the first and second components; and
Washing off and/or removing the electrically conductive particles that are not bonded to the electrical contacts.

At least one of the following elements is preferably provided with one or more functional groups, as already described: the particles, the first contacts, the second contacts. All of the foregoing and subsequent disclosure regarding functionalization of the particles, the first contacts, and/or the second contacts applies equally to the method described herein.

According to one embodiment, the method further comprises a step of functionalizing only the particles with a functional group and a step of binding at least a portion of the particles via weak interaction with at least one of the first contacts and the second contacts. In other words, only the particles may be functionalized and bonded via weak interaction with the first and/or second contacts.

According to one embodiment, the method further comprises:
Functionalizing the particles with a functional group;
Functionalizing at least one of the first contacts and the second contacts with a functional group; and
covalently bonding at least a portion of the particles with at least one of the first contacts and the second contacts.

In other words, the particles and the first and/or second contacts can be functionalized. In case of functionalizing both binding partners, i.e. particles and first or second contacts, the particles can be bonded to the respective binding partner (i.e. first or second contacts) via a covalent bond. In case of functionalizing only one binding partner, i.e. particles or first or second contacts, the particles can be bonded to the respective binding partner (i.e. first or second contacts) via weak interaction.

The above suspension comprises a solvent as a base substance with at least one of the following substances: Water, ethanol.

After applying the suspension to at least one of the components, a drying step is preferably carried out in which the at least one component is dried.

The electronics unit can also be heated for a short time above the melting point of the particles contained in the electrically conductive structure. Heating of the unit can be carried out, for example, in a reflow oven at temperatures between 40° C. and 250° C. This causes the individual particles to melt and form a massive conductive solid, which electrically and mechanically connects the opposing contacts. Alternatively or additionally, the particles and/or the underfill can be released and/or crosslinked by the ref ow process.

Furthermore, an electrically insulating material can be applied to at least one of the components, whereby applying the electrically insulating material may take place before or after the two components are assembled. In electronics manufacturing, especially flip chip assembly, the electrically insulating material is also referred to as underfill. The main reason for using underfill is the difference in thermal expansion coefficient between the silicon chip and the substrate. Without underfill, a change in temperature can create a very high stress on the chip-to-substrate bond, leading to fatigue and cracking. In addition, the underfill serves to prevent short circuits.

For example, an adhesive, especially an epoxy resin or a PU adhesive or an acrylate adhesive, can be used as the underfill or electrically insulating material.

According to the second option, nano- and/or microcapsules containing the electrically conductive particles are applied to at least one of the components. The encapsulation makes it possible to provide a defined mass or volume of particles or another substance at a specific location and to release it in a targeted manner via an activation mechanism.

With respect to the second option, the present disclosure relates to a method of manufacturing of an electronics unit with a first component with a plurality of first electrical contacts, such as in the form of an integrated circuit, and a second component with a plurality of second electrical contacts, wherein at least the following steps are performed:
Manufacturing and/or providing capsules (or first capsules) each containing one or more electrically conductive particles,
Applying the capsules to at least one of the components (e.g. as a suspension or powder),
Arranging the first and second components at a predetermined distance, with opposing first and second contacts, wherein applying the suspension may take place, for example, before or after arranging of the first and second components;
Activating the capsules so that the electrically conductive particles are released and arrange themselves on the electrical contacts of the at least one component and form an electrically conductive structure comprising a single or a plurality of the electrically conductive particles.

According to a preferred embodiment of the present disclosure, a suspension is prepared in which the capsules are contained as a suspended matter. The suspension is then applied to one or both of the components. Alternatively, the capsules can also be applied to the component(s) as a powder or paste, optionally with the additional aid of a template.

A wide variety of processes for the production of nano- or microcapsules are known from the prior art. For example, it Is possible to produce capsules by solvent evaporation, thermogelling, gelation, interfacial polycondensation, polymerization, spray drying, fluidized bed, droplet freezing, extrusion, supercritical fluid, coacervation, air suspension, pan coating, co-extrusion, solvent extraction, molecular incorporation, spray crystallization, phase separation, emulsion, in situ polymerization, interfacial deposition, emulsification with a nanomole sieve, ionotropic gelation method, coacervation phase separation, matrix polymerization, Interfacial crosslinking, congealing method, centrifugation extrusion, and/or one or more other methods.

The shell of the capsules containing the electrically conductive particles is preferably functionalized so that the capsules bind particularly strongly to the metal surface of the electrical contacts, for example by means of weak Interaction and/or covalent binding. Alternatively or additionally, the electrical contacts and possibly also the particles themselves can be functionalized. All the preceding and following disclosures relating to functionalizing the particles, the first contacts and/or the second contacts apply equally to the method described here.

According to one embodiment of the present disclosure, the capsules (“capsules”) with the particles therein are functionalized with one or more thiol groups. The electrical contacts are preferably not functionalized, but optionally the first contacts, the second contacts, or both the first and second contacts may be functionalized. With respect to functionalizing the capsules and/or the electrical contacts, all of the foregoing disclosure applies equally.

According to one embodiment, the method further comprises a step of functionalizing only the capsules (also called first capsules) with a functional group and a step of bonding at least part of the (first) capsules via weak interaction with at least one of the first contacts and the second contacts. In other words, only the (first) capsules may be functionalized and bonded via weak interaction with the first and/or second contacts. Optionally, the particles, the first contacts and/or the second contacts may be functionalized.

According to one embodiment, the method further comprises:
Functionalizing the (first) capsules with a functional group;
Functionalizing at least one of the first contacts and the second contacts with a functional group; and
covalently binding at least a portion of the (first) capsules to at least one of the first contacts and the second contacts.

In other words, the (first) capsules and the particles, the first and/or second contacts can be functionalized.

The shell of the microcapsule or a coating on the surface of the microcapsules can include, but not limited to, for example, albumin, gelatin, collagen, agarose, chitosan, starch, carrageenan, polystarch, polydextran, lactides, glycolides and co-polymers, polyalkyl cyanoacrylate, polyanhydride, polyethyl methacrylate, acrolein, glycidyl methacrylate, epoxy polymers, gum arabic, polyviyl alcohol, methyl cellulose, metal, metal nanoparticles, carboxymethyl cellulose, Hydroxyethyl cellulose, arabinogalactan, polyacrylic acid, ethyl cellulose, polyethylene, polymethacrylate, polyamide (nylon), polyethylene vinyl acetate, cellulose nitrate, silicones, poly(lactide-co-glycolide), kerosene, camauba, spermaceti, beeswax, stearic acid, stearyl alcohols, glyceryl stearate, shellac, cellulose acetate phthalate, zein, hydrogels, or the like.

In order to release the substances contained in the capsules, the capsules can be specifically opened. This can also be referred to as “activating”. Activating can be achieved, for example, by changing the pressure, pH, UV radiation, osmosis, temperature, light intensity, humidity, ultrasound, induction, addition of water, enzymes or the like. Thus, the time point at which the substances contained in the capsules are released can be precisely controlled.

The capsules according to the present disclosure are preferably activated after the first and second components have been assembled.

For example, simple core-shell capsules, capsules with cationic or anionic character, capsules with multiple shells or multiple layers of shell material (so-called multilayer microcapsules), granules can be used as capsules.

The capsules can be single capsules or pail of a multi-capsule system, which can have several capsules, which can optionally be connected to each other. With a multi-capsule system, such as a Iwo-component capsule system (2C capsule system), it is possible to release different substances in a defined amount or a defined ratio. It is emphasized here that the components of a multi-capsule system may consist of several unconnected capsules or of several connected capsules.

The individual capsules of a multi-capsule can be the same or different. They can differ, for example, in their shell material, shell thickness, size, capsule content or activation mechanism.

From US 2012/0107601 A1, for example, a capsule system is known that reacts to pressure and releases liquids accordingly. Other capsule systems are known from WO 2017/192407 A1, U.S. Pat. No. 8,747,999 B2, WO 2017 042709 A1, WO 2016/049308 A1, and WO 2018/028058 A1.

According to a preferred embodiment of the present disclosure, the electrically conductive particles are contained in first capsules, which in turn can optionally each be connected to at least one second capsule. The second capsules can be empty or can contain, for example, an electrically insulating material (underfill), or another desired material.

Alternatively, separate capsules that are not connected to other capsules can be used. According to one embodiment of the present disclosure, a first group of capsules containing electrically conductive particles is provided, and a second group of capsules containing a second material, in particular an underfill, is provided. The two groups can be applied simultaneously or subsequently to the component(s) of the electronics unit.

The method can further comprise a step of applying second capsules comprising an electrically insulating material to at least one of the first component and the second component.

According to one embodiment, one or more of the following is functionalized with one or more functional groups: the first electrical contacts, the second electrical contacts, the particles, the first capsules containing the conductive particles, the second capsules containing the insulating material, first interspaces of the first component between directly neighboring first electrical contacts, and second interspaces of the first component between directly neighboring second electrical contacts.

In particular, in a multi-capsule system comprising first and second capsules, which may optionally be connected, a heterogeneous functionalization of the complementary binding partners can be provided, in which the functionalization of the first capsules and the second capsules can be different. Alternatively or additionally, the functionalization of the first and second contacts may be different from a functionalization of the first and second interspaces.

For example, between directly neighboring first electrical contacts of the first component there may be first interstices or interspaces, and between directly neighboring second electrical contacts of the second component there may be second interstices or interspaces, which may be opposite the first interstices. To form the conductive structures between the opposing first and second electrical contacts with the particles contained in the first capsules, the first capsules and at least one of the first and second contacts can be functionalized such that the first capsules bind to the first and/or second contacts. For example, the first capsules can be functionalized with a thiol group or amines and the first and/or second electrical contacts can be functionalized with the corresponding complementary functionalization, such as a thiol group or a carboxyl group. Optionally, the particles can also be functionalized, for example analogously to the first capsules with thiol group or amines, to ensure binding of the particles to the first and/or second contacts. However, other complementary functionalizations, as explained above and below, are possible.

Alternatively or additionally, it can be provided to functionalize the second capsules and the first and/or second interspaces of the first and/or second component. This functionalization can optionally differ from the functionalization of the first capsules, the electrical contacts and/or the particles. This can ensure that the second capsules are deposited in the interspaces and the first capsules are deposited between the electrical contacts.

For example, the second capsules can be functionalized with amines or a thiol group and the first and/or second interspaces can be provided with the corresponding complementary functionalization, such as a carboxyl group or thiol group. However, other complementary functionalizations, as explained above and below, are possible.

For example, the size of the first capsules can be approximately the size of the electrical contacts in one dimension (e.g., the length or width of the contacts for rectangular contact areas).

According to a preferred embodiment of the present disclosure, the size of the second capsules corresponds approximately to the size of a distance between two neighboring electrical contacts of the same component. This can reduce the distance between directly neighboring contacts of the first component or the second component. It can also reduce the size of the electronics unit and/or increase the circuit density or contact density of the first and/or second contacts.

The first and second capsules, for example, can be activated one after the other. However, they can also be activated simultaneously.

The time-delayed activation of the second capsules can be achieved, for example, by the second capsules having a thicker shell than the first capsules and/or a different shell material compared to the first capsules. Alternatively, delayed and/or sequential activation of the first and second capsules can be accomplished by an increase in temperature and/or an increase in pressure and/or by other means, such as different activation mechanisms for activating the first and second capsules. For example, the first capsules can be activated at a first time point by heating to a first temperature and the second capsules can be activated at a second time point, subsequent to the first time point, by heating to a second temperature higher than the first temperature.

The shells of the first capsules and the shells of the second capsules can comprise an at least partially crosslinked (co)polymer. Sequential or subsequent activation of the first and second capsules can be achieved by different degrees of crosslinking of the (co)polymers of the shells of the first and second capsules. Alternatively or additionally, different activation mechanisms can be used to activate the first and second capsules. For example, the first capsules may be activated by temperature and/or temperature-induced activation and the second capsules may be activated by pressure and/or pressure-induced activation or otherwise.

At least one of the capsules of a multiple capsule system is preferably functionalized. Optionally or additionally, the first contacts and/or the second contacts can also be functionalized. According to a preferred embodiment of the present disclosure, the first capsules containing the electrically conductive particles are functionalized with one or more functional groups. The second capsules containing the electrically insulating material are preferably not functionalized, but can optionally be functionalized.

In principle, a functional group can be connected to the element in question either directly or via a so-called linker. The choice of linker can essentially determine the distance between the functionalized element (particle and/or electrical contact and/or capsule) and a second element to which the functionalized element selectively binds. Possible linkers include, for example, biopolymers, proteins, silk, polysaccarides, cellulose, starch, chitin, nucleic acid, synthetic polymers, homopolymers, DNA, halogens, polyethylenes, polypropylenes, Polyvinyl chloride, polylactam, natural rubber, polyisoprene, copolymers, random copolymers, gradient copolymer, alternating copolymer, block copolymer, graft copolymers, arcylnitrile butadiene styrene (ABS), Styrene-acrylonitrile (SAN), buthyl rubber, polymer blends, polymer alloy, inorganic polymers, polysiloxanes, polyphosphazenes, polysilazanes, ceramics, basalt, isotactic polymers, syndiodactic polymers, atactic polymers, linear polymers, crosslinked polymers, elastomers, thermoplastic elastomers, thermosets, semi-crystalline linkers, thermoplastics, cis-trans polymers, conductive polymers, supramolecular polymers.

In one embodiment, the first capsules and the second capsules can be linked to each other via one or more of the aforementioned linkers. In particular, the first capsules and second capsules can be covalently linked to each other.

Further aspects of the present disclosure relate to one or more electronics units manufactured in accordance with one or more methods of manufacturing described above and below.

Exemplary embodiments are described below with reference to the figures. The illustrations in the figures are schematic and not to scale. If the same or similar reference signs are used in the following description of the figures, these designate the same or similar elements.

### BRIEF DESCRIPTION OF THE FIGURES

The present disclosure is explained in more detail below by way of example with reference to the accompanying drawings. Showing:

FIG. 1 an electronics unit with two components that are electrically connected to each other via an electrically conductive structure consisting of a plurality of electrically conductive particles;

FIG. 2 the electronics unit of FIG. 1 with an additional underfill;

FIG. 3 an electronics unit with two components and additional spacers;

FIG. 4-10 different states of a method of manufacturing an electronics unit with two electronic components, in which a suspension containing electrically conductive particles as suspended matter is applied to one of the components before the two components are assembled together;

FIG. 11-15 different states of a method of manufacturing an electronics unit with two electronic components, hi which a suspension containing electrically conductive particles as suspended matter is applied to both components of the electronics unit after the components have been assembled;

FIG. 16-21 different states of a method of manufacturing an electronics unit with two electronic components, in which a suspension containing the particles in capsules is applied to one of the components before the two components are assembled.

### DETAILED DESCRIPTION OF EMBODIMENT EXAMPLES

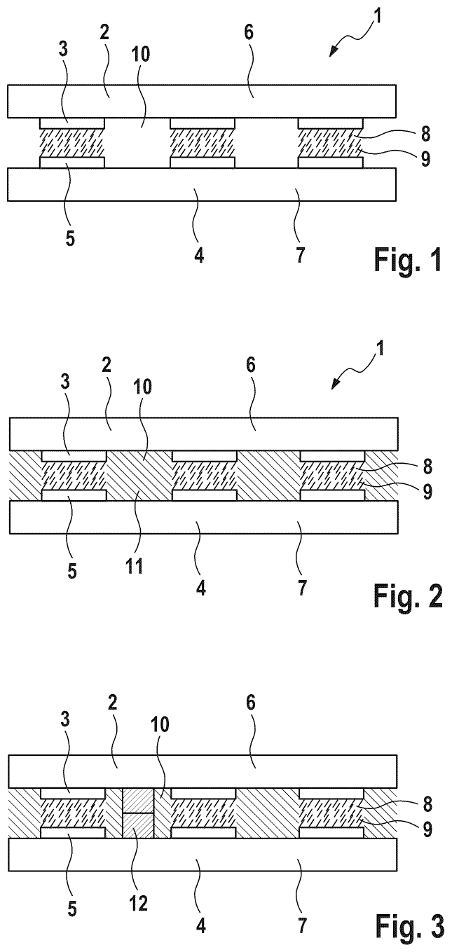

FIG. 1 shows an electronics unit 1 with two components 2, 4 which are electrically connected to each other via an electrically conductive structure 8 consisting of a plurality of electrically conductive particles 9.

The first component 2 comprises, for example, an integrated circuit 8 and can be, for example, a die or an housed (packaged) chip that has several electrical contacts 3 arranged next to each other on one surface. The second component 4 can be, for example, a chip housing, another chip, a printed circuit board or any other substrate 7, which also has several electrical contacts 5 arranged at a distance from one another.

The electrically conductive particles 9 are preferably micro- or nanoparticles, which may be, for example, gold, silver or copper, tin, zinc or various alloys; or a base metal with a contact surface to the surface made of another metal. In the illustrated embodiment, the particles are rod-shaped nanoparticles aligned parallel, side-by-side in a predetermined direction, while in contact with each other.

Due to the small size of the particles 9, the distance between the opposing contacts 3, 5 of a contact pair is particularly small and can be, for example, 500 nm or less.

The electrically conductive particles 9 and/or the contacts 3 or 5 are preferably functionalized, so that the particles 9 preferably bind to the electrical contacts 3, 5.

FIG. 2 shows the arrangement of FIG. 1, with an additional electrically insulating material 11—the so-called underfill—being present in an interspace 10 between neighboring contact pairs 3, 5. The underfill can be, for example, an epoxy resin, a PU adhesive or an acrylate adhesive, plastic, polymer.

FIG. 3 shows an alternative embodiment of the electronics unit 1 in which each component 2, 4 comprises a spacer 12 which is dimensioned such that the opposing contact surfaces of the contacts 3, 5, when the two components 2, 4 are assembled together, are separated by a predetermined distance. In the illustrated embodiment, the spacers are realized as projections projecting outwardly from the components 2, 4 and are made of a non-conductive material. In all other respects, the electronics unit 1 shown in FIG. 2 has an identical structure to the electronics unit 1 of FIG. 1, so that reference is made to the description there.

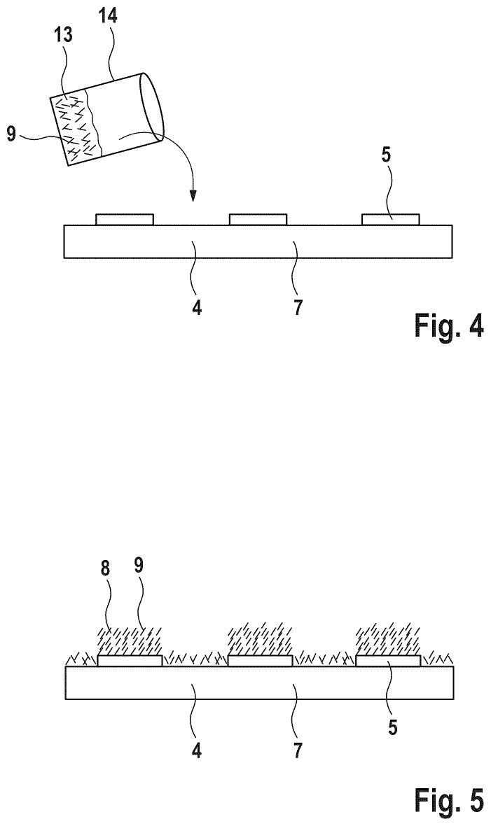

FIGS. 4 to 10 show different states of a method of manufacturing an electronics unit 1, in which a suspension 13 containing electrically conductive particles 9 as suspended matter is applied to one of the components 2, 4 before the two components 2, 4 are assembled together.

Here, the particles 9 are functionalized with a thiol group and therefore selectively bind with the metal surfaces of the electrical contacts 5. In addition, the electrical contacts 5 may also be functionalized and have one or more functional groups.

FIG. 4 shows how a suspension 13 containing the electrically conductive particles 9 is poured from a vessel 14 onto the second component 4.

FIG. 5 shows a state in the method of manufacturing in which the electrically conductive particles 9 accumulate on the metal surfaces of the second electrical contacts 5 due to their functionalization. In the interspaces 10 between neighboring electrical contacts 5, on the other hand, the bonding effect is less strong or non-existent, so that fewer conductive particles 9 are present there.

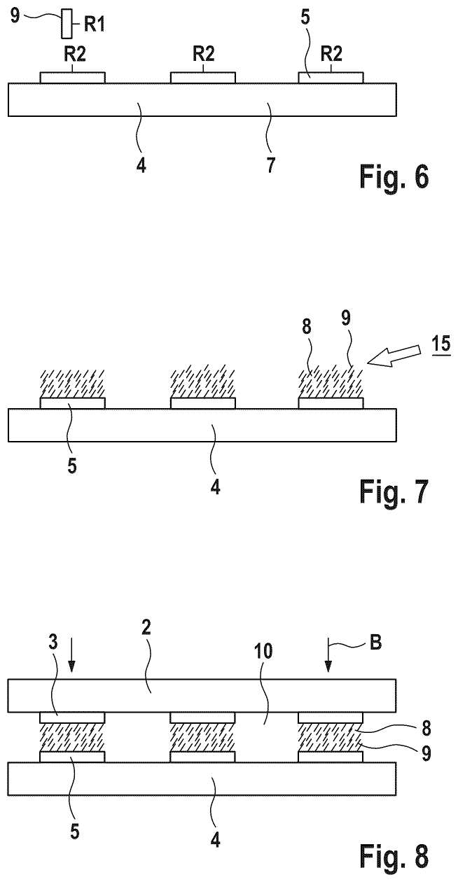

FIG. 6 shows an exemplary further embodiment in which both the electrically conductive particles 9 and the second electrical contacts 5 are functionalized. Here, the electrically conductive particles 9 comprise a first functional group R1, such as a carboxyl group, and the electrical contacts 5 comprise a second functional group R2, such as primary amines. The two functional groups R1, R2 in turn selectively bind particularly strongly to each other, so that the desired agglomeration of electrically conductive particles 9 on the electrical contacts 5 occurs.

FIG. 7 shows a further method step in which the electrically conductive particles 9 that do not adhere to the surface of the second component 4 are washed off using a washing liquid 15. The washing liquid 15 can be, for example, water, ethanol or a mixture thereof. Alternatively, compressed air or another fluid could be used for the washing process. The washing off of the non-bonded conductive particles 9 preferably takes place in a fluid flow. With regard to the flow rate of the fluid, care must be taken to ensure that it is not too high so as not to unintentionally detach the particles 9 arranged on the electrical contacts 5.

In FIG. 8, the two electronic components 2, 4 are assembled together opposite contacts 3, 5 so that they are electrically connected via the agglomerate of electrically conductive particles 19.

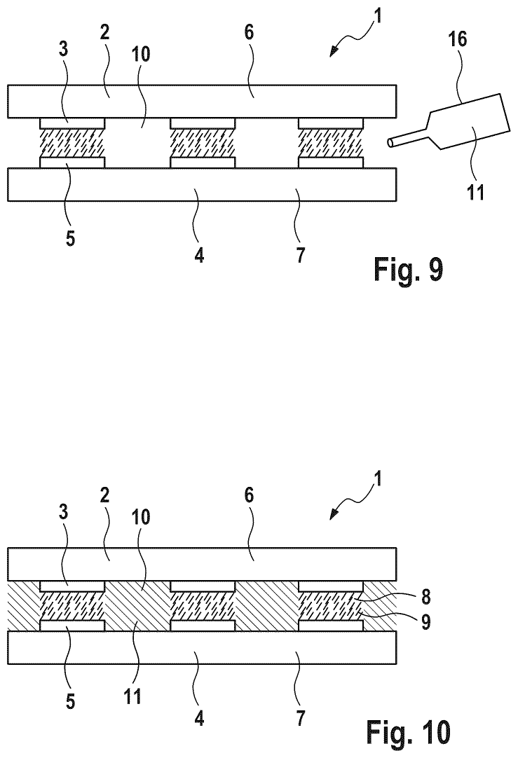

FIG. 9 shows the application of an underfill 11 into the interspaces 10 between neighboring contact pairs 3, 5 of the electronics unit 1. The underfill can be applied, as known from electronics manufacturing, e.g. by means of a metering device at the edge area of the electronics unit 1 and then flows into the interspaces 10 of the electronics unit 1 due to capillary effects until these are filled with the underfill 11. The underfill can be, for example, an adhesive, such as an epoxy resin, or another electrically insulating material. The result is a very compact electronics unit 1 as shown in FIG. 10.

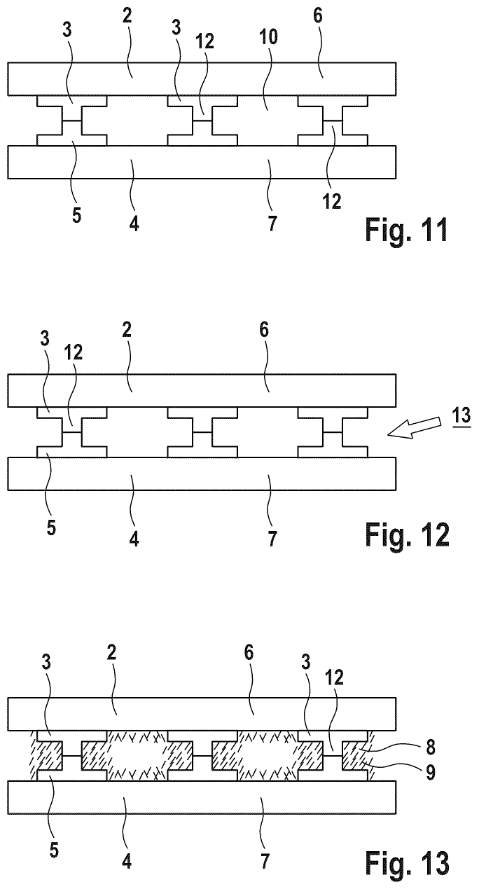

FIGS. 11 to 15 show different states of a method of manufacturing an electronics unit 1, in which electrically conductive particles 9 are applied in the form of a suspension 13 after the two components 2, 4 have been assembled together.

FIG. 11 shows an electronics unit 1 with two electrical components 2, 4, each with a plurality of area-like contacts 3, 5. The components 2, 4 are arranged with opposing electrical contacts 3, 5, whereby the first electrical contacts 3 and the second electrical contacts 5 are in contact. In the illustrated embodiment, the first and second electrical contacts 3, 5 each have a portion projecting beyond the remaining contact area, which serves as a spacer 12. The remaining contact surfaces are spaced apart.

After the components 2, 4 have been assembled together, a suspension 13 is applied in which the electrically conductive particles 9 are contained as suspended matter. This is shown in FIG. 12.

The electrically conductive particles 9 are functionalized by means of a thiol group and therefore preferentially attach to the metal surface of the electrical contacts 3, 5. The free space remaining between the opposing contact surfaces of the electrical contacts 3, 5 fills with electrically conductive particles 9, as shown in FIG. 13.

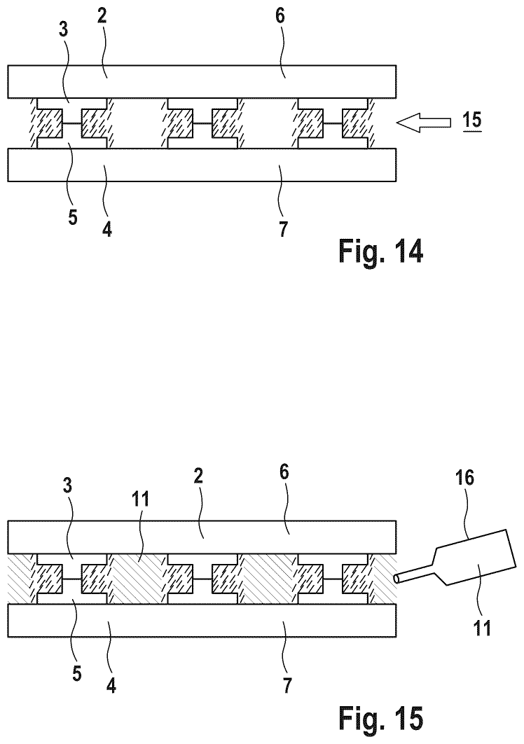

FIG. 14 shows a method step in which electrically conductive particles 9 that are not bonded to a metal surface are washed off by means of a washing liquid 15. As previously described, the wash solution may contain water, ethanol or another fluid.

Finally, in FIG. 15, an underfill 11 is added as described above with respect to FIG. 10.

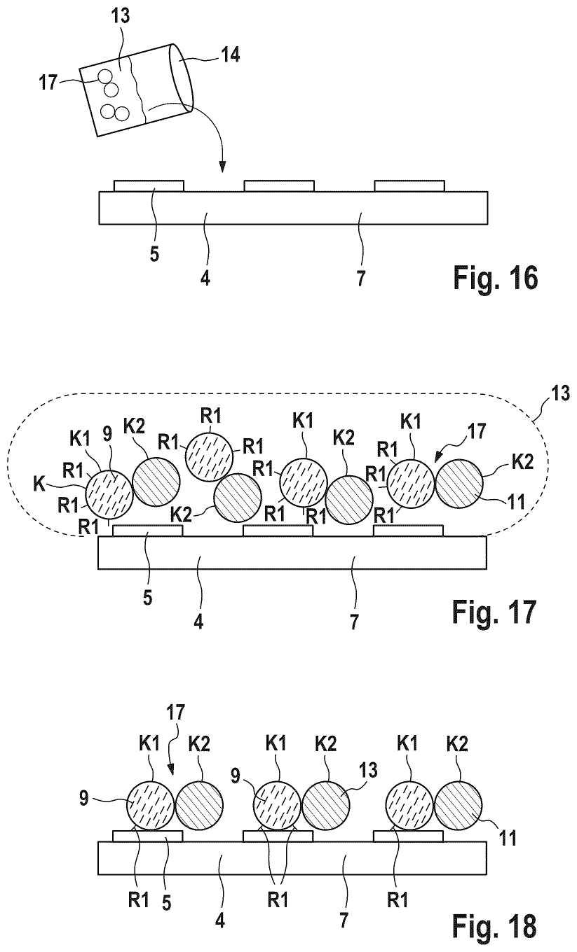

Furthermore, FIGS. 16 to 21 show various states of a method of manufacturing an electronics unit 1, in which the electrically conductive particles 9 are applied in the form of capsules K. The method is described in detail below.

In the embodiment shown, double-capsules are used, comprising a first capsule K1 and a second capsule K2, which are connected to each other. The first capsules K1 contain the electrically conductive particles 9; the second capsules K2 contain an electrically Insulating material 11 or the underfill. The capsules K can be manufactured in a known method as described hereinabove. A connection between two capsules K1, K2 to form a double-capsule can be achieved, for example, by functionalization, as also described in the general part of the description.

Firstly, FIG. 16 shows the application of a suspension 13 with a plurality of double-capsules 17 contained in the suspension 13 as suspended matter. In this case, the suspension 13 is simply poured onto the surface of the second electronic component 4, whereby the double-capsules 17 are evenly distributed on the surface. The first capsules K1 containing the nanoparticles are functionalized with a thiol group and therefore bind particularly strongly to the metal surfaces of the second contacts 5.

The size of the first capsules K1 corresponds approximately to the size of the contact area of the electrical contacts 5, while the size of the second capsules K2 corresponds approximately to the distance 10 between two neighboring electrical contacts 5. The second capsules K2 are not functionalized. After applying the suspension 13 to the surface of the second component 4, the double-capsules 17 are arranged as shown in FIGS. 17 and 18. A first capsule K1 lies on each contact surface of an electrical contact 5; the second capsules K2 essentially fill the space between neighboring electrical contacts 5.

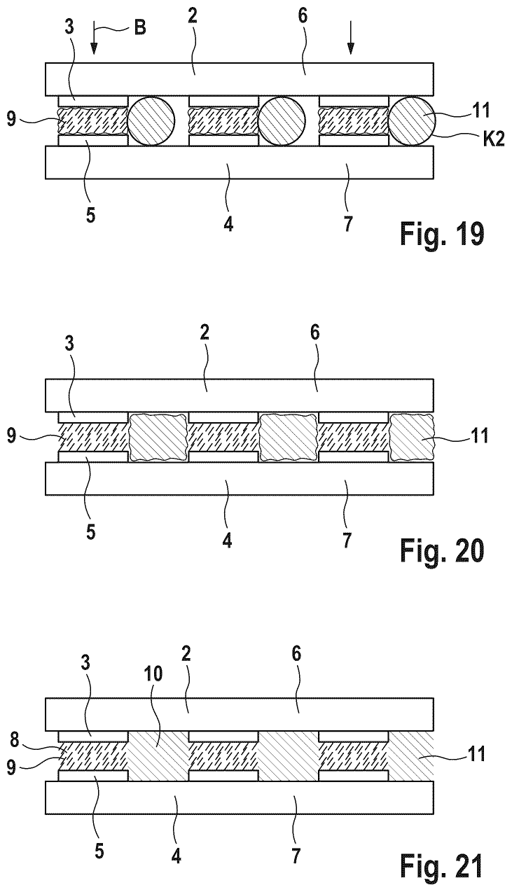

In a next method step, the first electronic component 2 is placed on the second component 4 so that the contact surfaces of the first and second components 2, 4 lie opposite each other at a predetermined distance (see FIG. 19, arrow B). The desired distance between the components 2, 4 is again achieved by spacers 12 (not shown).

Thereafter, the first capsules K1 are first activated by increasing the temperature so that they release the nanoparticles 9 contained therein. The nanoparticles 9 are functionalized by means of a thiol group so that they bind selectively with the metal surface of the first and second contacts 3, 5. Optionally or additionally, the electrical contacts 3, 5 can also be functionalized.

In a next step, the second capsules K2 are activated (see FIG. 20) so that they release the underfill 11 contained therein. The delayed activation of the second capsules K2 can be achieved, for example, by the second capsules K2 having a thicker shell and/or a different shell material compared to the first capsules. Alternatively, this could be done by further increasing the temperature or the pressure or by other means. The underfill 11 then spreads into the spaces between the electrical contacts 3, 5 and firmly bonds the two components 2, 4 together, as shown in FIG. 20. The finished electronics unit Hs shown in FIG. 21.

The shells of the first capsules and the shells of the second capsules can have at least partially crosslinked (co)polymer. Sequential or subsequent activation of the first and second capsules can be achieved by different degrees of crosslinking of the (co)polymers of the shells of the first and second capsules. Alternatively or additionally, different activation mechanisms can be used to activate the first and second capsules.

The contacting of the first and second contacts 3, 5 by means of microparticles or nanoparticles 9 used here makes it possible to produce a very low packing density and a correspondingly small and compact electronics unit 1. In addition, this method is particularly simple and inexpensive.

It should be noted in addition that “comprising” and “having” do not exclude other elements or steps, and the indefinite articles “one” or “a” do not exclude a plurality.

Furthermore, it should be noted that features or steps that have been described with reference to one of the above embodiments may also be used in combination with other features or steps of other embodiments described above. Reference signs in the claims are not to be regarded as limitations.

1: A method of manufacturing an electronics unit with a first component with a plurality of first electrical contacts, comprising an integrated circuit, and a second component with a plurality of second electrical contacts, the method comprising:
providing capsules each containing one or more electrically conductive particles,
applying the capsules to at least one of the first component and the second component,
arranging the first component and the second component at a predetermined distance, with the first electrical contacts and the second electrical contacts opposing each other; and
activating the capsules so that the one or more electrically conductive particles are released and arrange on at least one of the first component on the first electrical contacts and the second component on the second electrical contacts, and form an electrically conductive structure comprising the one or more electrically conductive particles.

2: The method of manufacturing an electronics unit according to claim 1, wherein the capsules are activated after the first component and the second component have been arranged with the first electrical contacts and the second electrical contacts opposing each other.

3: The method of manufacturing an electronics unit according to claim 1, wherein the one or more electrically conductive particles are contained in first capsules, and
wherein the method further comprises:
applying second capsules comprising an electrically insulating material to at least one of the first component and the second component.

4: The method of manufacturing an electronics unit according to claim 1, wherein the one or more electrically conductive particles are contained in first capsules, and the first capsules are each connected to at least one second capsule, which has an electrically insulating material, and
wherein the first capsules and the at least one second capsule are applied to at least one of the f component and the second component.

5-6. (canceled)

7: The method of manufacturing an electronics unit according to claim 3, wherein the first capsules and the at least one second capsule are activated sequentially in time.

8: The method of manufacturing an electronics unit according to claim 3, wherein at least one of the following elements is functionalized with a functional group:
the capsules,
the first capsules,
the one or more electrically conductive particles,
the first electrical contacts,
the second electrical contacts, and
the second capsules comprising the electrically insulating material.

9. (canceled)

10: The method according to claim 1, further comprising:
functionalizing the capsules with a functional group;
functionalizing at least one of the first electrical contacts and the second electrical contacts with a functional group; and
covalently bonding at least part of the capsules to at least one of the first electrical contacts and the second electrical contacts.

11: A method of manufacturing an electronics unit with a first component comprising an integrated circuit and a plurality of first electrical contacts, and a second component with a plurality of second electrical contacts, the method comprising:
providing a suspension in which one or more electrically conductive particles are contained as suspended matter,
applying the suspension to at least one of the first component and the second component so that an electrically conductive structure comprising the one or more electrically conductive particles is formed on at least one of the first component on the first electrical contacts and the second component on the second electrical contacts,
arranging the first component and second component at a predetermined distance, with the first electrical contacts and the second electrical contacts goosing each other: and
washing off the one or more electrically conductive particles from a surface of the at least one of the first component and the second component that is not covered by the first electrical contacts or the second electrical contacts.

12: The method of manufacturing an electronics unit according to claim 11, further comprising:
functionalizing at least one of the following elements with a functional group:
the one or more electrically conductive particles,
the first electrical contacts, and
the second electrical contacts.

13. (canceled)

14: The method according to claim 11, further comprising:
functionalizing the one or more electrically conductive particles with a functional group;
functionalizing at least one of said first electrical contacts and said second electrical contacts with a functional group; and
covalently bonding at least a portion of the one or more electrically conductive particles to at least one of the first electrical contacts and the second electrical contacts.

15-16. (canceled)

17: The method of manufacturing an electronics unit according to claim 11, wherein after manufacturing the electrically conductive structure, an electrically insulating material is applied to at least one of the first component and the second component.

18. (canceled)

19: An electronics unit, comprising:
a first component with a plurality of first electrical contacts and comprising an integrated circuit, and
a second component with a plurality of second electrical contacts,
wherein the first electrical contacts and the second electrical contacts are each electrically connected to each other via an electrically conductive structure comprising a plurality of electrically conductive particles.

20. (canceled)

21: The electronics unit according to claim 19, wherein the electrically conductive particles are rod-shaped nanoparticles aligned in parallel in a predetermined direction and in direct contact with each other.

22: The electronics unit according to claim 19, wherein the second component is a housing, chip, circuit board, or other substrate.

23: The electronics unit according to claim 19, wherein the first component is an unhoused chip.

24: The electronics unit according to claim 19, wherein at least one of the following is functionalized by bonding with a functional group:
the electrically conductive particles,
the first electrical contacts, and
the second electrical contacts.

25. (canceled)

26: The electronics unit according to claim 24, wherein only the electrically conductive particles are functionalized with a functional group; and/or
wherein the first electrical contacts and the second electrical contacts each have no functionalization, such that the electrically conductive particles are bonded via weak interaction with at least one of the first electrical contact and the second electrical contacts.

27: The electronics unit according to claim 24, wherein the electrically conductive particles are functionalized with a functional group; and
wherein at least one of said first electrical contacts and said second electrical contacts is functionalized with a functional group such that said electrically conductive particles are covalently bonded to at least one of said first electrical contacts and said second electrical contacts.

28: The electronics unit according to claim 24, wherein the functional group comprises at least one thiol group and/or carboxyl group.

29: The electronics unit according to a claim 19, wherein at least one of the first component and the second component comprises spacers dimensioned such that opposing contact areas of the first electrical contacts and the second electrical contacts are spaced apart when both the first component and the second component are assembled.

30. (canceled)
